(19) United States
(12) Patent Application Publication
(10) Pub. No.: US 2012/0326260 A1
(43) Pub. Date: Dec. 27, 2012

(54) PHOTODIODE THAT INCORPORATES A CHARGE BALANCED SET OF ALTERNATING N AND P DOPED SEMICONDUCTOR REGIONS

(76) Inventors: William French, San Jose, CA (US); Peter J. Hopper, San Jose, CA (US); Philipp Lindorfer, San Jose, CA (US); Vladislav Vashchenko, Palo Alto, CA (US)

(21) Appl. No.: 13/165,050

(22) Filed: Jun. 21, 2011

(51) Int. Cl. H01L 31/06; H01L 31/18

(52) U.S. Cl. 257/461; 438/57; 257/E31.037; 257/E31.001

(57) ABSTRACT

A photodiode comprises a first terminal formed in a surface of a semiconductor substrate; a second terminal formed in the substrate surface and spaced apart from the first terminal; and a plurality of adjacent alternating N-type and P-type diffusion regions formed in the substrate surface between the first terminal and the second terminal.

### FIELD OF THE INVENTION

The disclosed subject matter relates to a photodiode that incorporates a charge balanced set of alternating N and P doped semiconductor regions.

### BACKGROUND OF THE INVENTION

Silicon photodiodes are constructed from single crystal silicon wafers similar to those used in the manufacture of integrated circuits. A major difference between the two is that silicon photodiodes require higher purity silicon. The purity of the silicon is directly related to its resistivity, with higher resistivity indicating higher purity. The resistivity could vary from 10 Ohm-cm to 10,000 Ohm-cm.

When light shines on crystalline silicon, electrons within the crystal lattice may be freed. Only photons within a certain level of energy can free electrons in the semiconductor material from their atomic bonds to produce an electric current. This level of energy, known as the “bandgap energy,” is the amount of energy required to dislodge an electron from its covalent bond and allow it to become part of an electrical circuit. To free an electron, the energy of a photon must be at least as great as the bandgap energy. Photons with more energy than the bandgap energy will expend that extra amount of energy as heat when freeing electrons. Crystalline silicon has a bandgap energy of approximately 1.1 electron-volts (eV), which means that the wavelength where it begins to absorb is λ=he/E_{g}, where λ is the wavelength of light, E_{g} is the bandgap energy of the material, h is Plank's constant and c is the speed of light.

The photon energy of light varies according to the different wavelengths of the light. The entire spectrum of sunlight, from infrared to ultraviolet, covers a range of about 0.5 eV to about 2.9 eV. For example, red light has a photon energy of about 1.7 eV; blue light has a photon energy of about 2.7 eV.

Only a portion of sunlight exposed to silicon will be absorbed. FIG. 1 shows the absorption coefficient a versus wavelength λ, where, for silicon, wavelengths beyond about 1 μm are not absorbed. Also, as shown in FIG. 2, the depth at which light is absorbed in silicon, and photo-carriers are generated, will also vary.

It is very important that, when photo-carrier electron-hole (e-h) pairs are generated in the silicon, they are within an electric field. Otherwise, electron-hole pairs will recombine before they can diffuse away from each other. If an electric field exists, then electron-hole pairs will be accelerated away from each other before they can recombine.

Cross sections of two typical silicon photodiodes are shown in FIGS. 3 and 4. FIG. 3 shows a vertical implementation. FIG. 4 shows a lateral implementation.

The FIG. 3 photodiode implementation includes a vertical P-i-N diode 300 which is reverse biased so that the light-generated carriers are separated before they recombine and are swept with a high electric field to the positive (V+) and negative (V−) contacts. The FIG. 3 design provides a large depletion region 302, but requires a discrete process flow. This means that all of the electrons must be added externally, for example on a printed circuit board (PCB). The inherent losses from both resistive ohmic drops and parasitic capacitance, makes the FIG. 3 photodiode structure less than ideal.

FIG. 4 shows a traditional lateral photodiode structure 400 that is commonplace in monolithic integrated circuit (IC) designs. In the FIG. 4 structure 400, the interface between a Deep N-type region (DNWELL) 402 and a P-type region (PWELL) 404 forms a junction. When light penetrates the silicon surface 406, it is absorbed by the silicon at different depths according to its wavelength and generates e-h pairs. If the light is absorbed in the silicon region away from the depletion region 408, then the generated e-h pairs can recombine almost instantly. If the light penetrates to the depletion region 408, then the generated e-h pairs are separated by the electric field in the depletion region 408 and are swept away to the positive (V+) and negative (V−) contacts to form an electric current. Therefore, it is critical that the ion implants that form the DNWELL 402 region, the PWELL region 404 and the NWELL region 410 be at the particular energy that will form a junction at the depth necessary to absorb the required wavelength(s) of light. As mentioned above, any light that is absorbed outside of a depletion region is “lost.” That is, the generated e-h pairs recombine and no current is collected. The efficiency of the FIG. 4 photodiode is, therefore, limited.

Additionally, a silicon nitride, silicon monoxide or silicon dioxide layer may be deposited on top of the silicon surface to serve as protection as well as to act as an anti-reflective coating. This protective layer is then masked and etched so that the area above the collecting junction is open to the light.

### SUMMARY

Disclosed embodiments provide a photodiode formed in a semiconductor substrate. The photodiode comprises a first terminal formed in a surface of the substrate; a second terminal formed in the substrate surface and spaced apart from the first terminal and a plurality of adjacent, alternating N-type and P-type diffusion regions formed in the substrate surface between the first terminal and the second terminal.

The features and advantages of the various embodiments of the invention disclosed herein will be more fully understood and appreciated upon consideration of the following detailed description and the accompanying drawings, which set forth illustrative embodiments of the claimed subject matter.

### BRIEF DESCRIPTION OF THE DRAWINGS

FIG. 1 is a graph showing absorption coefficient versus wavelength for identified materials.

FIG. 2 is a graph showing light penetration depth in silicon versus wavelength.

FIG. 3 is a cross section drawing illustrating a typical vertical implementation of a silicon photodiode.

FIG. 4 is a cross section drawing illustrating a typical lateral implementation of a silicon photodiode.

FIG. 5A is a perspective drawing illustrating a lateral super-junction LDMOS transistor structure.

FIG. 5B is a cross section drawing illustrating a vertical super-junction LDMOS transistor.

FIG. 5C is a perspective drawing illustrating a V-groove super-junction LDMOS transistor.

FIG. 6 is a perspective drawing illustrating a super-junction photodiode structure.

FIG. 7 is a perspective drawing illustrating the depletion region of the FIG. 6 super-junction photodiode structure.

FIG. 8 is a graph showing the responsivity of photodiodes made from silicon and germanium.

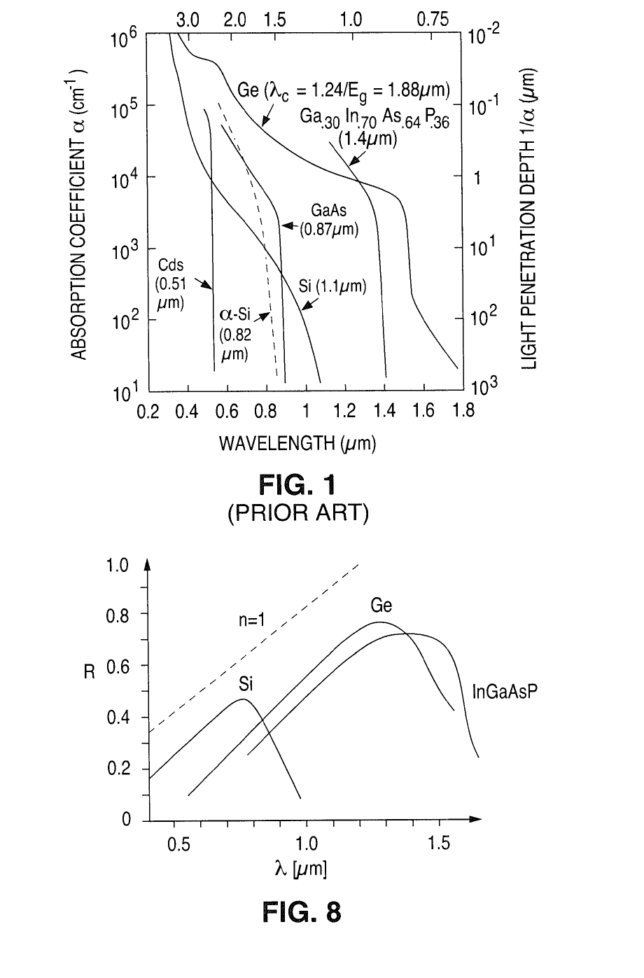

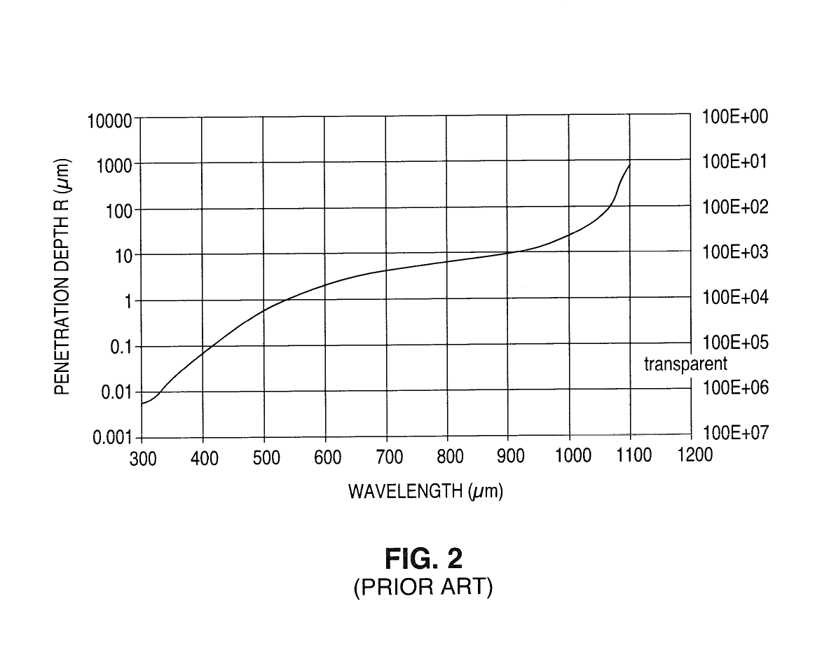

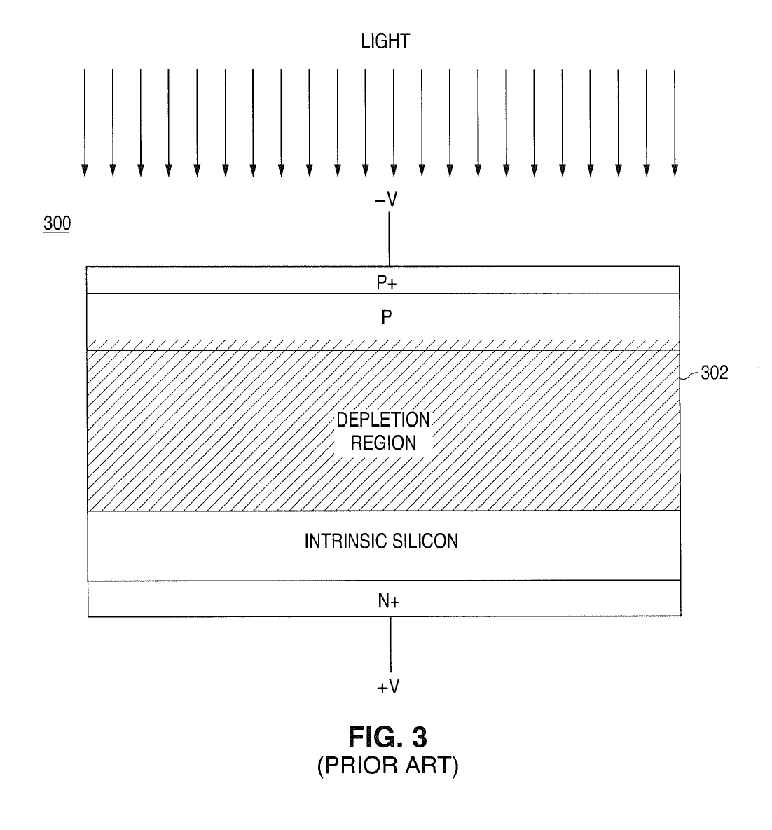

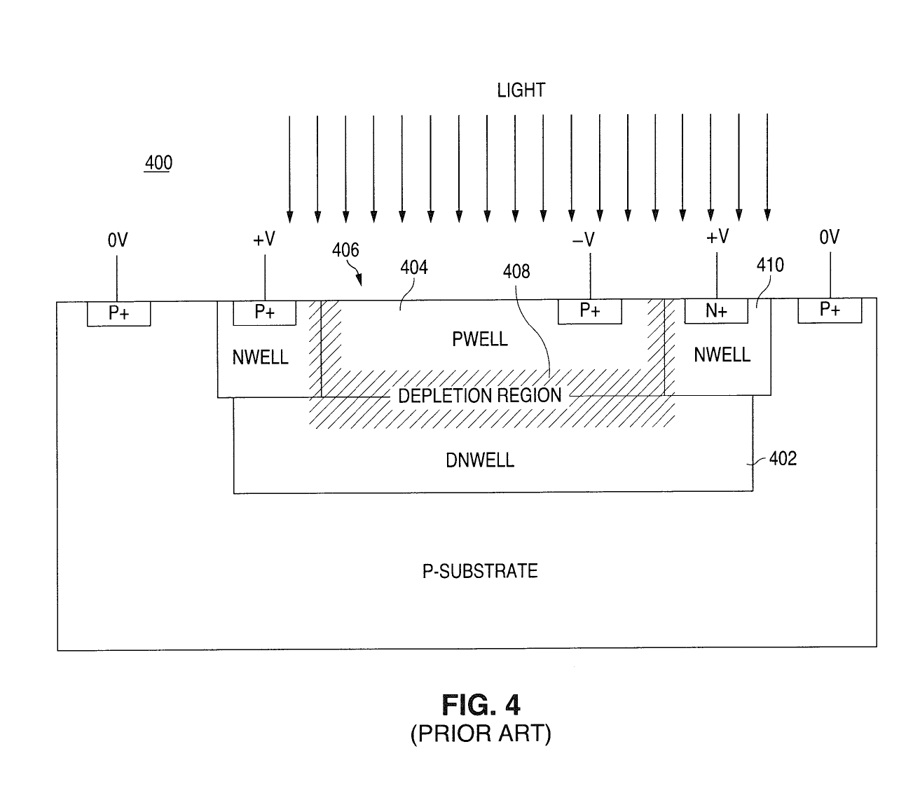

### DETAILED DESCRIPTION

The concept of a “super-junction” or charge balanced device is well known, but only as a method by which a high voltage breakdown may be obtained, typically in a laterally diffused metal oxide semiconductor (LDMOS) structure, thereby allowing a reduction in the resistance-area product (RDSON*Area) of the LDMOS device.

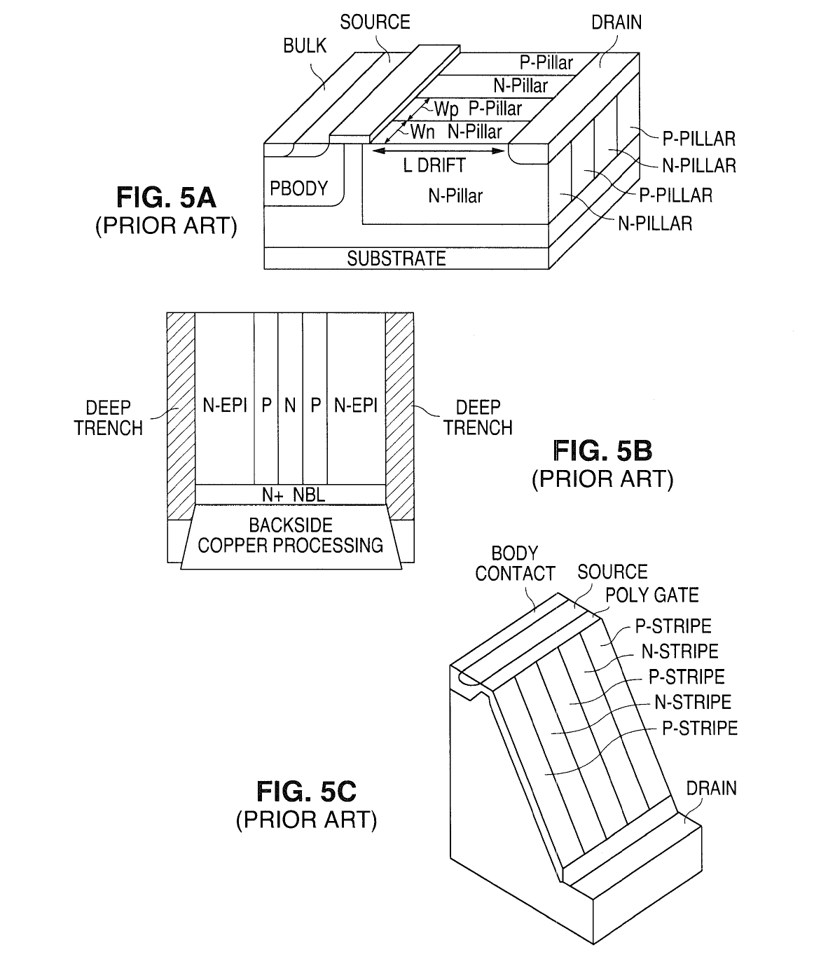

The super-junction LDMOS concept has a number of different known implementations, but fundamentally consists of a series of alternating N- and P-type regions, typically called pillars. These pillars may be arrayed in different configurations, such as laterally, vertically or at an angle, as shown in FIGS. 5A, 5B and 5C, respectively. In all of each these LDMOS structures, the effect is the same: by adjusting the doping level and the width (Wn and Wp) of the pillar regions, it is possible to cause a state of full depletion either at zero applied bias or with a reverse bias applied across the junction. This state is called “charge balance,” which means that the N and P regions are fully depleted. Once charge balance is achieved, the entire region becomes one large charge collector.

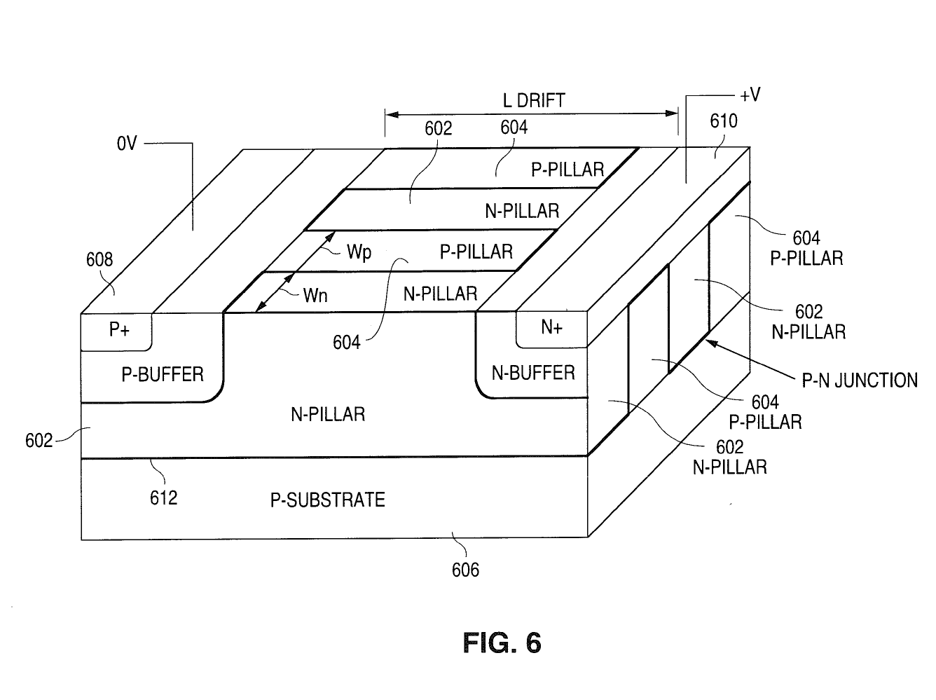

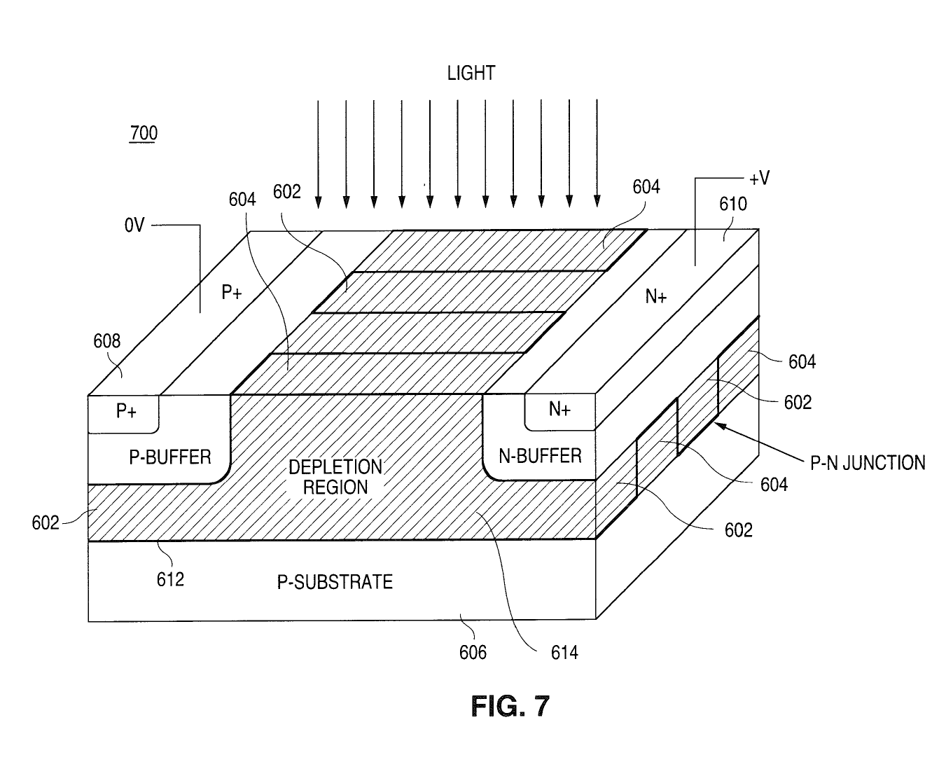

FIG. 6 shows an embodiment of a super-junction photodiode structure 600 wherein the adjacent, alternating N-pillar diffusions 602 and P-pillar diffusions 604 are formed in a P-type semiconductor substrate 606 between a P+ cathode terminal 608 and an N+ anode terminal 610 and are arrayed across the surface of the device. FIG. 6 shows 0V applied to the cathode terminal 608 and a positive voltage V+ applied to the anode terminal 610. The P-N junction 612 is highlighted as bold in the FIG. 6 drawing. This junction 612 forms the center of the depletion region 614, which is shown in FIG. 7. As is evident from FIG. 7, the size of the depletion region 614 has been maximized to the fullest volume possible. Any light that is absorbed from the surface to the bottom of the N- and P-pillar regions 602, 604 will cause e-h pair creation. Because of the built-in electric field in the depletion region 614, all of these carriers are separated before they can recombine and by drift and diffusion, they will reach the anode and cathode terminals.

It should be noted that, by design, the sensitivity of the super-junction photodiode 600 can be altered. Low doping and smaller pillar widths (Wn, Wp) would allow the silicon to be fully depleted at zero voltage, thereby facilitating a low power solution. Higher doping levels (and/or wider Wn and Wp pillar regions) would give full depletion at some larger reverse bias voltage. This would result in a lower resistance cell (higher conductivity) and the higher voltage would provide higher electric fields for a faster, more sensitive cell.

Typically, photodiodes are operated in a reverse bias mode. That is, a positive voltage is applied to the N-type regions. This causes the depletion region to expand. It is, therefore, desirable to use a super-junction photodiode design that can sustain a high reverse voltage. However, this is limited to the breakdown voltage of the photodiode junction. By using the charge balance concept described above, the breakdown voltage of the super-junction photodiode is much larger than could otherwise be obtained. In addition, the super-junction structure causes a constant electric field across the drift region (Ldrift in FIG. 6) between the anode and the cathode. The carriers are therefore at a constant rate across the entire depletion region. This means that a large drift region may be used where the electric field accelerates carriers uniformly through the entire volume. This also results in carriers being accelerated faster, which should result in faster operation of the device.

The super-junction photodiode 600 discussed above assumes that only pure silicon has been used as the material within which the N- and P-type pillars are created 602, 604. Those skilled in the art will appreciate that alternate materials could also be used that have a different bandgap and, therefore, would absorb a different spectrum of light. For example, in FIG. 7, instead of a silicon substrate, a germanium substrate could be used, or a layer of germanium or silicon-germanium (SiGe) could be grown on top of the silicon substrate before the implants are performed. The resultant absorbed wavelengths would change, as shown in FIG. 8. The wavelength range of the photo-detector 600 would, therefore, shift to higher wavelengths.

It is also possible to create a photodiode where the N- and P-type pillars shown in the FIG. 6 embodiment are formed with alternating materials such as, for example, Si/SiGe/Si/SiGe . . . . The resultant super-junction photodiode would absorb light with a much broader spectrum. This type of device could be formed in two ways: etching of the silicon regions and selective epitaxial growth (SEG) of silicon germanium (SiGe), or implanting germanium into certain pillars with the other pillars masked.

It should be understood that the particular embodiments of the subject matter described above have been provided by way of example and that other modifications may occur to those skilled in the art without departing from the scope of the claimed subject matter as expressed in the appended claims and their equivalents.

1. A super-junction photodiode formed in a semiconductor substrate, the super-junction photodiode comprising:
a first terminal formed longitudinally in a surface of the semiconductor substrate;
a second terminal formed longitudinally in the semiconductor substrate surface and spaced apart from the first terminal; and
a plurality of adjacent, alternating N-type and P-type diffusion pillars formed laterally in the semiconductor substrate surface between the first terminal and the second terminal forming a lateral fully depleted charge balanced super junction region.

2. The super-junction photodiode of claim 1, wherein the semiconductor substrate comprises silicon.

3. The super-junction photodiode or claim 1, wherein the semiconductor substrate comprises germanium.

4. The super-junction photodiode of claim 1, and further comprising:
first voltage supply connected to provide a first voltage to the first terminal, and,
a second voltage supply connected to provide a second voltage to the second terminal, the second voltage being greater than the first voltage.

5. A super-junction photodiode formed in a semiconductor substrate, the super-junction photodiode comprising:
a cathode terminal formed longitudinally in a surface the semiconductor substrate;
an anode terminal formed longitudinally in the surface of the semiconductor substrate and spaced apart from the cathode terminal; and
a plurality of adjacent, alternating diffusion pillars having first and second conductivity types and formed laterally in the semiconductor substrate between the cathode terminal and the anode terminal forming a lateral fully depleted charge balanced super-junction region,

6. The super-junction photodiode of claim 5, wherein the semiconductor substrate comprises silicon.

7. The super-junction photodiode of claim 5, wherein the semiconductor substrate comprises germanium.

8. The super-junction photodiode of claim 5, wherein the semiconductor substrate comprises a silicon substrate having a layer of germanium formed thereon.

9. The super-junction photodiode of claim 5, wherein the semiconductor substrate comprises a silicon substrate having a layer of silicon-germanium formed thereon.

10. The super-junction photodiode of claim 5, wherein the alternating diffusion pillars comprise alternating materials.

11. The super-junction photodiode of claim 10, wherein the alternating materials comprise silicon (Si) and silicon-germanium (SiGe).

12. A method of fabricating a super-junction photodiode in a semiconductor substrate, the method comprising:
forming a first terminal longitudinally in the semiconductor substrate surface,
forming a second terminal longitudinally in the semiconductor substrate surface that is spaced apart from the first terminal, and
forming a plurality of adjacent, alternating diffusion pillars having first and second conductivity types in the semiconductor substrate surface laterally placed between the first and second terminals wherein said alternating diffusion pillars form a lateral fully depleted charge balanced super-junction region.

13. The method of claim 12, wherein the semiconductor substrate comprises silicon.

14. The method of claim 12, wherein the semiconductor substrate comprises germanium.

15. The method of claim 12, wherein the semiconductor substrate comprises a silicon substrate having a layer of germanium formed thereon.

16. The method of claim 12, wherein the semiconductor substrate comprises a silicon substrate having a layer of silicon-germanium formed thereon.

17. The method of claim of claim 12, wherein the alternating diffusion pillars comprise alternating materials.

18. The method of claim 17, wherein the alternating materials comprise silicon (Si) and silicon-germanium (SiGe).
